(19) United States
(12) Patent Application Publication
(10) Pub. No.: US 2006/0162955 A1
(43) Pub. Date: Jul. 27, 2006

(54) Test card assembly

(76) Inventor: Warren Stuart Crippen, Mesa, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/354,556

(22) Filed: Feb. 14, 2006

Related U.S. Application Data
(63) Continuation of application No. 10/074,003, filed on Feb. 14, 2002, now abandoned.

(51) Int. Cl. H05K 1/03; H05K 1/00

(52) U.S. Cl. 174/250

(57) ABSTRACT

A space transformer and a method for making the space transformer. An electrically conductive material is placed in an inner region located in a silicon medium, the silicon medium defining both a first side and a second side at an outer region thereof Electrical contact is established between the electrically conductive material in the inner region and both the first side and the second side of the silicon medium at the outer region to provide double-sided electrical contacts for the space transformer.

### CROSS-REFERENCE TO RELATED APPLICATION

The instant application is a Continuation Application of and claims the priority date of U.S. patent application Ser. No. 10/074,003 entitled “Silicon Space Transformer and Method of Manufacturing Same,” filed Feb. 14, 2002 and assigned to the assignee of the present invention.

### BACKGROUND OF THE INVENTION

The present invention generally relates to space transformers and to methods of manufacturing space transformers.

Before integrated circuits, such as those including microelectronic dies, are packaged in an electronic component, such as a computer, they must be tested. Testing is essential to determine whether a circuit's electrical characteristics conform to its design specifications.

In order to perform such testing, test card assemblies typically include three major components. The first component is a test card printed circuit board, the second component is a space transformer and the third component is a probe head. The test card printed circuit board is electrically coupled to a test system on a macro pitch scale, while the probe head is electrically coupled to a microelectronic die being tested, such as a semiconductor chip, on a micro pitch scale. The space transformer is the device that allows interconnection between the two physical scales mentioned above. The space transformer thus translates the macro pitch scale of the printed circuit board to the micro pitch scale of the probe head, providing electrical connection of these devices and enabling microelectronic dies to be tested by allowing signal and power/ground connections to be made. A space transformer may be used to probe either contact locations on a single microelectronic die, or contact locations on a silicon having a plurality of microelectronic dies thereon. Individual space transformers are generally produced by creating several such space transformers on a semiconductor wafer or substrate, using conventional processes such as deposition and photolithography. The space transformers are tested prior to singulating (separating) the wafer into individual space transformers.

Conventional space transformers are typically provided in the form of multi-layer substrates involving alternating layers of an insulating material, such as ceramic, and patterned layers of an electrically conductive material, such as copper. Existing technology for making space transformers generally involves the build-up of the necessary circuitry on ceramic, such a process requiring multiple deposition and a co-firing process. The known techniques for making space transformers are both costly and time consuming.

The prior art fails to offer a space-saving a space transformer that can be manufactured in a cost-effective and efficient manner.

### BRIEF DESCRIPTION OF DRAWINGS

The present invention is illustrated by way of example and not limitation in the figures in the accompanying drawings in which like references indicate similar elements, and in which:

FIG. 1 is a schematic representation of a bare silicon wafer into which a plurality of vias is being formed according to one embodiment of the present invention;

FIG. 2 is a schematic representation similar to FIG. 1, showing a layer of adhesion promoter as having been deposited on the silicon wafer of FIG. 1, according to an embodiment of the present invention;

FIG. 3a is a schematic representation similar to FIG. 1, showing a layer of copper as having been deposited on the layer of adhesion promoter of FIG. 2, according to an embodiment of the present invention;

FIG. 3b is a schematic representation showing the contact pattern of FIG. 3a as having been patterned based on a predetermined contact pattern for the build up of the space transformer, according to an embodiment of the present invention;

FIG. 4 is a schematic representation showing a silicon layer as having been disposed on the layer of copper of FIG. 3a to provide a silicon-electrical conductor sandwich, according to an embodiment of the present invention;

FIG. 5 is a schematic representation of an intermediate space transformer according to any one of standard silicon manufacturing processes and incorporating the silicon-electrical conductor sandwich shown in FIG. 4;

FIG. 6 is a schematic representation showing a space transformer made by removing a back side of the intermediate space transformer of FIG. 5 to expose electrical contact zones at the bottom of vias provided therein;

FIG. 7a is a schematic representation of a space transformer made according to an embodiment of the method of the present invention; and

FIG. 7b is a schematic representation depicting a space transformer made according to the prior art.

### DETAILED DESCRIPTION

Embodiments of the present invention contemplate the use of silicon as a medium for space transformation. Silicon advantageously provides an identical coefficient of thermal expansion as the conventional silicon dies being tested. Space transformers of the prior art, however, such as those using ceramics as the substrate, disadvantageously present coefficients of expansion that are occasionally mismatched with respect to silicon dies that they are coupled to. In addition, working with silicon advantageously involves well-defined processes that do not require multiple co-firing steps as in the case of ceramics. The fabrication of silicon-based space transformers can be performed utilizing standard semiconductor fabrication equipment and processes. Ceramic processing, on the other hand, is typically very expensive, as ceramic itself is much more expensive than silicon. In addition, ceramic processing is relatively lengthy, since it requires that, for each layer of the space transformer, an amount of precursor material be applied then fired to form the ceramic, this process being known as co-firing.

Given the capabilities of existing semiconductor fabrication equipment, according to embodiments of the present invention, the generation of the device-level features on a space transformer using silicon and the development of the land grid array features on the transformer are simplified. Using silicon as the medium for space transformation reduces device thicknesses, radically reduces the cost and lead-time for the devices, and improves device reliability.

In the context of embodiments of the present invention, “land grid array” geometries refer to the size and spacing of surface features of the space transformer, typically measured in mils (10.sup.-3 inch) as opposed to semi-conductor geometries which are typically measured in microns. Conventional land grid array pads and spacing are at least an order of magnitude larger than semi-conductor pads and spacing. For example, typical pads for a land grid array might be, in a largest dimension thereof, between about 10 to 50 mils, with a pitch substantially equal to the pad size. However, typical pads for semiconductor devices might be between about 10 to 100 microns in their largest dimension, with a pitch substantially equal to about twice the pad size. The “largest dimension” mentioned above may, for example, be a diameter of a pad if the pad is circular, or a side dimension of the pad if the pad is square or rectangular. Ceramics are manufactured on an order of magnitude similar to that of circuit boards, that is, the metal and dielectric layers are mils in thickness. However, semi-conductors utilize metal and dielectric layers that are microns in thickness. Therefore, space transformers with a given number of layers in silicon can theoretically be about twenty five times thinner than their ceramic counterparts.

Device reliability is improved by manufacturing space transformers with silicon among other things because, while silicon processing is well understood and widely practiced, ceramic processing is less well understood and not nearly as widely practiced. The problems inherent in manufacturing reliable silicon devices are relatively well understood and are being addressed more readily than those inherent in manufacturing reliable ceramic devices.

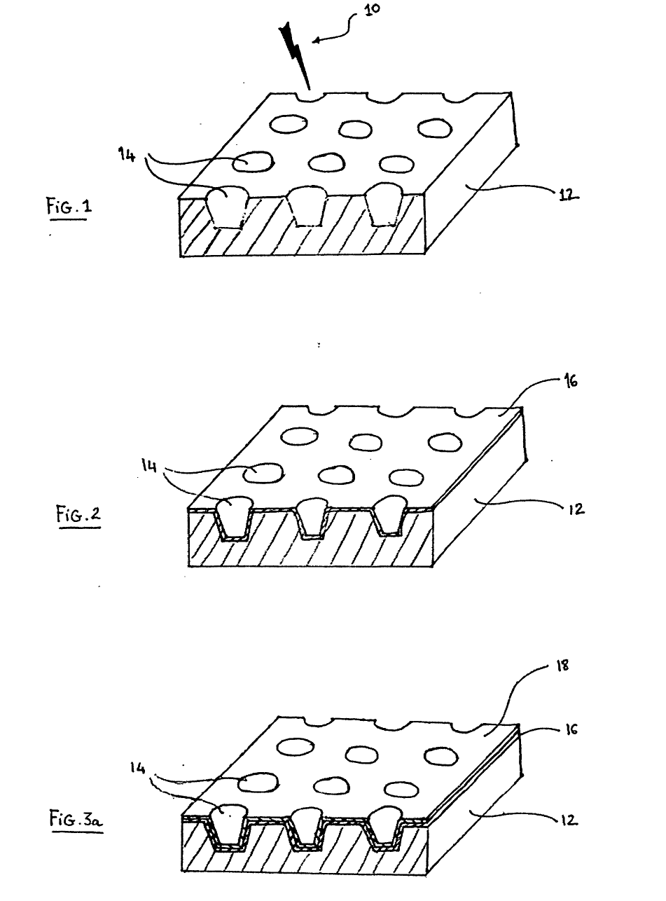

According to an embodiment of the present invention, as will be described in further detail with respect to FIGS. 1-6, a bare silicon wafer is provided, onto which vias are formed, for example using laser drilling techniques, in a pattern that matches the pad layout of the dies to be tested. Thereafter, a thin layer of an adhesion promoter, such as silicon oxide, is deposited onto the silicon wafer and into the vias. A layer of an electrically conductive material, such as copper, is then deposited on the layer of adhesion promoter, the thickness of the electrically conductive material being selected based on the deposition technology being employed, and being optimized for signal transfer. Then, the required contact pattern is defined, for example using standard photolithography techniques, and the build up of the space transformer is continued as required to ensure proper interconnect, power, ground and signal patterns depending on application needs. Thereafter the backside of the space transformer is removed, for example using a selective plasma etch process, to expose the electrically conductive material at the bottom of the vias. The space transformer may then be singulated from the wafer and used in a test tool in a conventional manner.

It is to be noted that embodiments of the present invention are not limited to the provision of a plurality of vias in the silicon substrate, but that they include within their scope the provision of a single via as well, the number and configuration of vias being a function of the electrical contact configuration to be provided on the side of the space transformer where the vias are to be exposed.

Silicon has not been used to date as the medium for space transformers at least due to the inability of the silicon to provide double-sided electrical contacts. The use of the vias, the provision of a layer of an electrically conducting material such as copper on the silicon, and the selective etch back of the silicon to expose the copper at the bottom of the vias, enable the use of silicon as the medium for space transformers according to an embodiment of the present invention by providing double-sided electrical contacts on the silicon. By “double-sided electrical contacts,” what is meant in the context of embodiments of the present invention is that the medium used for the space transformer is provided with electrical contacts at a land grid array side thereof adapted to be coupled to a land grid array, and at another, die side thereof adapted to be coupled to the microelectronic die to be tested. At least some of the pads on the land grid array side are electrically coupled to at least some of the pads on the die side of the space transformer. Double-sided electrical contacts are essential for a space transformer to function. Although one embodiment of the present invention contemplates the use of copper to establish double-sided electrical contacts, it is to be understood that embodiments of the present invention encompass the use of other electrical conductors, such as, for example, aluminum.

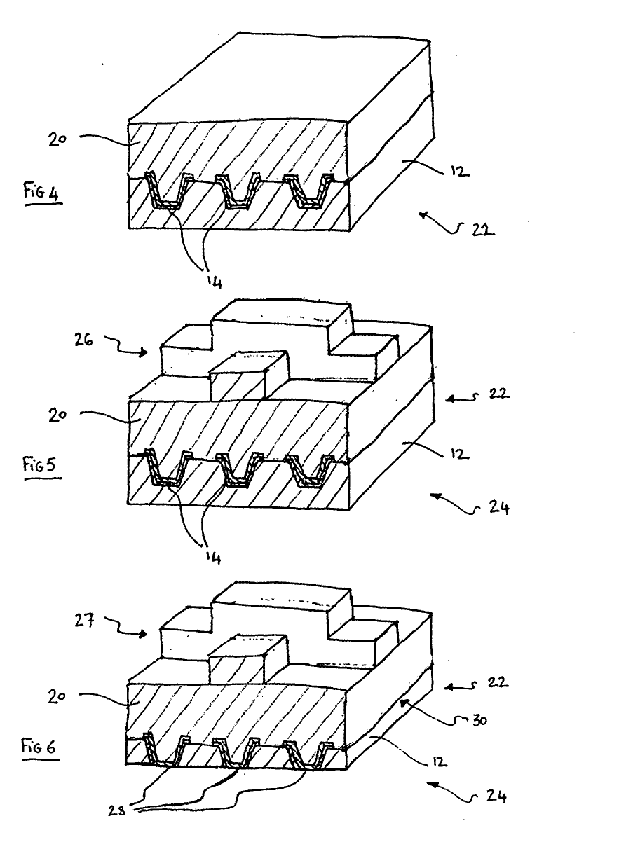

Turning now to the drawings, FIGS. 1-6 depict various stages of the fabrication of a space transformer according to an embodiment of the present invention. Referring more particularly, to FIG. 1, a method according to one embodiment of the present invention involves starting from a bare silicon wafer or substrate, and etching vias 14 into the silicon, for example using laser beams as depicted schematically by beams 10. A high density of relatively large vias may be provided onto the silicon medium. The range of vias per surface area that would quality as high density is dependent on the size of the vias, and can include the following possibilities provided by way of example only: for a 100 micron pitch and 50 micron vias, 361 vias/mm.sup.2; for a 150 micron pitch and 50 micron vias, 40 vias/mm.sup.2; and for a 200 micron pitch and 75 micron vias, 21 vias/mm.sup.2. Possible sizes of electrical contact zones created at the bottom of the vias (see electrical contact zones 28 in FIG. 6) include diameters of between about 25 and about 250 microns. However, the size of the vias depends on the particular die to be tested, as readily recognizable by a person skilled in the art.

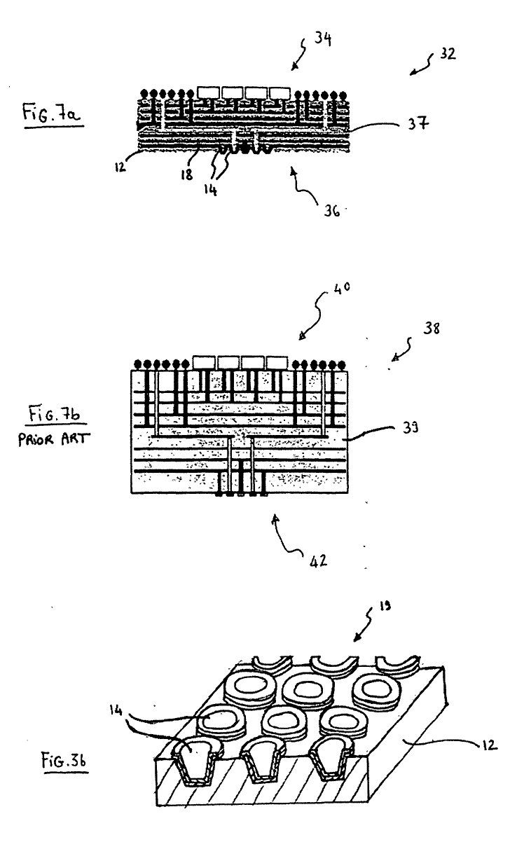

After creating the vias in the silicon wafer or space transformer medium 12, according to an embodiment of the present invention as depicted in FIG. 2, a layer of an adhesion promoter 16, such as, for example, silicon oxide, is deposited on the initial space transformer medium. The layer of adhesion promoter is of a thickness typically measured in Angstroms. Tantalum could in turn be deposited onto the silicon oxide to enhance its adhesion promotion properties. The purpose of the adhesion promoter is to enhance an adhesion of an electrical conductor layer thereon, as described in further detail with respect to FIG. 3a. Another alternative for an adhesion promoter includes trichlorosilane. As seen in FIG. 2, the adhesion promoter 16 is deposited on the top flat surface of the space transformer medium 12, and in the vias thereof. The adhesion promoter may be deposited by vapor deposition techniques, as recognized by a person skilled in the art. However, other deposition techniques, such as wet chemical deposition, are also possible.

Referring now to FIG. 3a, a layer of copper 18 is deposited on top of the layer of adhesion promoter 16 so as to at least partially fill vias 14 as shown. The deposition of the adhesion promoter and of the copper as depicted in FIGS. 2 and 3 may be achieved according to known methods as readily recognizable by one skilled in the art. For example, copper may be deposited onto the space transformer medium by using conventional plating methods. The thickness of the copper layer is predetermined as a function of the deposition technology, and is optimized for signal transfer. According to an embodiment of the present invention, the layer of adhesion promoter may have a thickness of between about 0.02 to 1.0 microns. The copper layer may have a thickness that is between about 10 to about 50 times thicker than the thickness of the adhesion layer. Thus, the copper may have a thickness of between about 0.2 to about 50 microns. It is to be noted that embodiments of the instant invention encompass layers of adhesion promoter and copper that have thicknesses other than the ones in the above-mentioned ranges, the thicknesses being a function of, among other things, the deposition processes being used and the metals being deposited. With regard to the copper layer, the optimization of the layer thickness for signal transfer is a function of the power to be transferred from one side of the space transformer to the other, and of the speed of the electrical signal to be transferred, as readily recognizable by one skilled in the art.

Referring next to FIG. 3b, the layer of copper 18 is shown as having been etched to define the predetermined contact pattern 19, using any one of known. It is noted that the contact pattern may differ from one application to the next, based on application needs, as readily recognized by one skilled in the art.

Referring now to FIG. 4, a schematic representation is provided showing a silicon layer 20 as having been disposed on the contact pattern 19 of FIG. 3b to provide a silicon-electrical conductor “sandwich” 22 according to one embodiment of the present invention. By “silicon-electrical conductor sandwich,” what is meant in the context of embodiments the present invention is that an electrical conductor, such as copper, is disposed between two silicon layers, such as, as in the case of the embodiment shown in FIGS. 4 and 5, the contact pattern 19 being sandwiched between the silicon layer 12 and the silicon layer 20. The silicon layer 20 has a sufficient thickness to allow conventional silicon device build up based on application needs using silicon processing techniques. According to one embodiment of the present invention, the silicon layer 20 is between about 1 micron and about 250 microns, although the stated range is not all-inclusive.

Referring next to FIG. 5, a schematic representation is provided of an intermediate space transformer 24 built up according to any one of standard manufacturing processes and incorporating the silicon-electrical conductor sandwich 22 shown in FIG. 4. The intermediate space transformer 24 incorporates standard build up layers 26.

As seen in FIG. 6, according to an embodiment of the present invention, the intermediate space transformer 24 of FIG. 5 may be etched for exposing electrical contact zones 28 at the etched face of the space transformer for providing a space transformer 27. It is to be understood that embodiments of the present invention include within their scope the fabrication of a plurality of space transformers through singulation. Thus, during the build up of layers 26, a plurality of intermediate space transformers could be formed which, after the etching process, are then singulated to yield a space transformer such as space transformer 27 shown in FIG. 6.

In the embodiment shown in FIG. 6, the electrical contact zones comprise exposed parts of the copper layer 12 disposed in vias 14. The electrical contact zones allow the space transformer to provide double-sided electrical contacts: while standard space transformer build-up as shown in FIGS. 4 and 5 allow electrical contacts on one side of the space transformer, the provision of vias 14 and the etch back of layer 12 allow the provision of electrical contacts on the opposite side of the space transformer. The electrical contact zones 28 on one side of the silicon medium, and electrical contact areas provided as a result of standard device build up on the opposite side of the silicon medium, together provide electrical contact regions that make the double-sided electrical contact possible for the space transformer according to embodiments of the present invention. The etching may be effected using conventional atmospheric downstream plasma etching technology, although it is to be understood that other conventional methods may be used, as readily recognizable by one skilled in the art. As is well known, plasma etching is a process that utilizes an electrically excited gas to remove material from a device or unit. Selective plasma etching refers to a process that removes only specific materials, such as, in the case of embodiments of the present invention as depicted in FIGS. 1-7a, removing only silicon and not the electrically conductive material.

Referring now to FIG. 7a, a space transformer 32 made according to one embodiment of the present invention is shown, such as the process described with respect to the embodiment of FIGS. 1-6 to make space transformer 27. The layer of copper 18 is shown as having been provided on the layer of silicon 12, the copper being exposed at the bottom of vias 14, and defining a contact pattern on the side of the layer of copper 18 opposite the layer of silicon 12. The space transformer 32 has a land grid array contact side 34, and a semiconductor contact side 36 as shown, and is made using silicon 37 as the space transformer medium according to one embodiment of the method of the present invention. Referring thereafter to FIG. 7b, a space transformer 38 according to the prior art is show. Space transformer 38 is made of ceramic 39, and includes a land grid array contact side 40 and a semi-conductor contact side 42 having the same profile, respectively, as land grid array contact side 34 and semi-conductor contact side 36 of the space transformer 32 according to the embodiment of the present invention shown in FIG. 7a. A comparison of FIGS. 7a and 7b reveals, among other things, that a space transformer with a given contact profile and made according to embodiments of the present invention is advantageously significantly thinner than a space transformer with the same contact profile and made according to the prior art. The use of silicon for the space transformer allows the use of known techniques for silicon processing, which in turn allows the manufacturing of the space transformer on a significantly smaller scale when compared to the manufacturing of space transformers using ceramic materials as their substrate.

Thus, according to one embodiment of the present invention, two-sided contact in a silicon wafer for a space transformer is established by providing an electrically conductive layer, such as a layer of copper, in between layers of silicon. Space transformers using ceramic material as their substrate are difficult and costly to manufacture, and, in addition, are bulky relative to silicon components. In addition, they disadvantageously tend to have different coefficients of expansion when compared with silicon, and thus tend to present problems in the testing of dies made of silicon. Embodiments of the present invention substantially eliminate the above problems of the prior art by providing a space transformer that uses silicon as its substrate, and that provides for double-sided electrical contact by creating a layer of an electrically conductive material within the silicon layers. The above may be achieved by laser drilling vias in a silicon wafer, depositing a layer of electrically conductive material, such as copper, in the wafer, building up the circuit for the space transformer, and thereafter thinning a back side of the built up wafer to expose pads of the electrically conductive material at the bottom of the vias with selective etch technology to allow for the silicon to provide the double-sided electrical contact typically seen in ceramic space transformers.

Embodiments of the present invention further encompass a space transformer comprising: a first silicon layer; a second silicon layer mounted to the first silicon layer; and means disposed in an inner region located between the first silicon layer and the second silicon layer for providing double-sided electrical contacts for the space transformer. An example of the means for providing comprises the layer of copper 8 shown in FIG. 3a, including the copper disposed in the vias 14. Other such means would be well known by persons skilled in the art.

The invention has been described with reference to specific exemplary embodiments thereof. It will, however, be evident to persons having the benefit of this disclosure, that various modifications and changes may be made to these embodiments without departing from the broader spirit and scope of the invention. The specification and drawings are, accordingly, to be regarded in an illustrative rather than in a restrictive sense.

1-17. (canceled)

18. A test card assembly comprising:
a test card printed circuit board having first contacts thereon;
a probe head having second contacts thereon; and
a space transformer comprising:
a silicon medium having a land grid array side and a semiconductor side opposite the land grid array side; and
a predetermined contact pattern comprising electrically conductive material disposed in an inner region of the silicon medium and defining electrical contact zones providing double-sided electrical contacts for the space transformer, the contacts comprising:
land grid array side contacts disposed on the land grid array side of the silicon medium and having their largest dimension and their pitch in the order of mils to define a macro-pitch scale, the land grid array side contacts further being adapted to be connected to corresponding ones of the first contacts; and
semiconductor side contacts disposed on the semiconductor side of the silicon medium and having their largest dimension and their pitch in the order of microns to define a micro-pitch scale, the semiconductor side contacts further being adapted to be connected to corresponding ones of the second contacts, the electrical contact zones further being disposed to convert a macro-pitch scale of the land grid array side contacts to the micro-pitch scale of the semiconductor side contacts.

19. The assembly according to claim 18, wherein the silicon medium comprises a first silicon layer and a second silicon layer, the contact pattern being disposed between the first silicon layer and the second silicon layer.

20. The assembly according to claim 18, wherein the second silicon layer defines at least one via therein, at least some of the electrically conductive material being located in the at least one via.

21. The assembly according to claim 18, further comprising an adhesion promoter disposed between the electrically conductive material and the first silicon layer.
